(19) United States
(12) Patent Application Publication
(10) Pub. No.: US 2025/0006725 A1
(43) Pub. Date: Jan. 2, 2025

(54) FAIL-SAFE AND FAIL-TOLERANT INPUT/OUTPUT INTERFACE IMMUNE FROM LATCHUP

(71) Applicant: STMicroelectronics International N.V., Geneva (CH)

(72) Inventor: Varun KUMAR, Nurmahal (IN)

(73) Assignee: STMicroelectronics International N.V., Geneva (CH)

(21) Appl. No.: 18/744,291

(22) Filed: Jun. 14, 2024

Related U.S. Application Data
(60) Provisional application No. 63/510,990, filed on Jun. 29, 2023.

(51) Int. Cl. H01L 27/02; H01L 21/8249

(52) U.S. Cl. CPC H01L 27/0262; H01L 21/8249

(57) ABSTRACT

The present disclosure is directed to an input/output (I/O) interface that includes a set of complementary metal-oxide semiconductor (CMOS) transistors in a P-type substrate. A first N-type region is in the substrate and a second N-type region in the substrate spaced from the first N-type region, the second N-type region being a deep-NWELL (DNW). A first heavily doped P-type region is between the first and second N-type regions, the first heavily doped P-type region is coupled to ground. A second heavily doped P-type region in the first N-type region, the second heavily doped P-type region and is coupled to an output terminal. A first heavily doped N-type region is in the first N-type region, the first heavily doped N-type region is coupled to a floating-Well (FW) terminal. A second heavily is doped N-type region in the second N-type region. A resistor is coupled to the DNW and the resistor is coupled to a voltage supply terminal.

### BACKGROUND

### Technical Field

The present disclosure is directed to a fail-safe and fail-tolerant input/output (I/O) interface based on a complimentary metal-oxide semiconductor (CMOS) layout immune from latchup.

### Description of the Related Art

Scaling down integrated circuits (ICs) is desired for low cost and low power applications. Accordingly, reducing dimensions of devices within an IC is a typical way for scaling down the IC. Generally smaller devices are designed to work with lower voltage. However, some ICs working as interface circuits such as input/output (I/O) buffers are coupled to external circuit components that may work in a different voltage level. For instance, the interface circuit may work in a 3.3V technology while the external circuit is working with a 5V technology. I/O interfaces are implemented based on a complimentary metal-oxide semiconductor (CMOS) layout that, in operation, includes some parasitic elements. The parasitic elements may cause latchup in the CMOS layout which damages or reduces efficiency of the IC. The latchup is a short circuit or a low impedance path between a high-voltage stage (e. g., coupled to a voltage supply) and a low-voltage stage (e. g., coupled to ground) which results in an unwanted current flow in the IC.

In the CMOS layout, the latchup may be created by parasitic elements between adjacent negative-type (N-type) or positive-type (P-type) regions. The latchup causes an electrical current leakage between the adjacent regions. A method of reducing the effect of the latchup in the CMOS layout is increasing distances between the adjacent regions. However, this method increases an area of the IC and consequently increases the cost of the manufacturing.

### BRIEF SUMMARY

The present disclosure is directed to an input/output (I/O) interface implemented based on a complimentary metal-oxide semiconductor (CMOS) layout that covers a smaller area than conventional designs. The I/O interface transmits and receives data signals to an external circuit. In various embodiments of the present disclosure, the I/O interface is transmitting data signals through an output driver to the external circuit coupled to a PAD contact. The output driver includes pull-up driver and pull-down driver. The pull-up driver includes at least one PMOS coupled between a first voltage supply and the PAD. The pull-down driver includes at least one NMOS coupled between the PAD and a ground node or a second voltage supply having lower voltage than the first voltage supply (hereinafter PMOS and NMOS refer to P-type and N-type metal-oxide-semiconductor field-effect transistor (MOSFET)). In an implementation of the CMOS IO driver layout, the PMOS is formed in an N-type well (N-Well) region and the NMOS is formed in a deep N-Well (DNW) region laterally spaced from the N-Well region. This is a standard way to eliminate parasitic SCR path. By making in this way the SCR which earlier was to be formed between PNP of PMOS and NPN of NMOS is barricaded by DNW. By using this layout, a new SCR is formed between the PNP of PMOS and DNW used to isolate NMOS device. In non-fail-safe or non-tolerant IO's the new formed SCR is not operational but, in fail-safe and fail-tolerant modes of operation of the I/O interface, this new layout configuration is a potential latchup prone structure.

This new SCR circuit includes a parasitic N-P-N BJT having an emitter terminal which is formed by the DNW region. In addition, the equivalent SCR circuit includes a parasitic P-N-P BJT having emitter and base terminals which are formed in the N-Well region. The latchup may be created when the emitter of the parasitic N-P-N BJT is coupled to a zero-volt supply or ground node. The latchup causes a current flow from the first voltage supply or the PAD to the zero-volt supply or ground node. In the present disclosure, a resistor is coupled to the emitter terminal of the parasitic N-P-N BJT to limit the current flow in the equivalent SCR circuit. The addition of the resistor reduces a gain of the parasitic N-P-N BJT and disconnects a loop created by the parasitic N-P-N and P-N-P BJTs. The resistor is implemented as an on-chip resistor connected to the DNW region. The second terminal of resistor is connected to Supply. The resistor causes the I/O interface being immune from the latchup without increasing a distance between the N-Well and DNW regions and instead, can reduce a distance between the N-Well and DNW regions. This can result in a reduction in silicon area or allow that saved space to be utilized by other components of the final device. Hence, an area of the CMOS layout is maintained in a smallest possible dimension regardless to the effect of the latchup.

### BRIEF DESCRIPTION OF THE SEVERAL VIEWS OF THE DRAWINGS

Aspects of the present disclosure are best understood from the following detailed description when read with the accompanying figures. It is noted that various features are not drawn to scale.

FIG. 1A is a topology of a transmit circuit, in accordance with some embodiments.

FIG. 1B is a topology of a circuit in accordance with the present disclosure.

FIG. 2 is a schematic circuit of FIG. 1B the present disclosure.

FIGS. 3A-3B are cross-sectional views of a MOS configuration of FIGS. 1B and 2.

FIG. 4 is a top down view of the circuit of FIG. 1B and 2.

FIG. 5 is a flowchart of a method of the present disclosure.

FIG. 6 is a cross-sectional view of a diode configuration of the present disclosure.

FIG. 7 is a top down view of the diode confirmation of FIG. 6.

### DETAILED DESCRIPTION

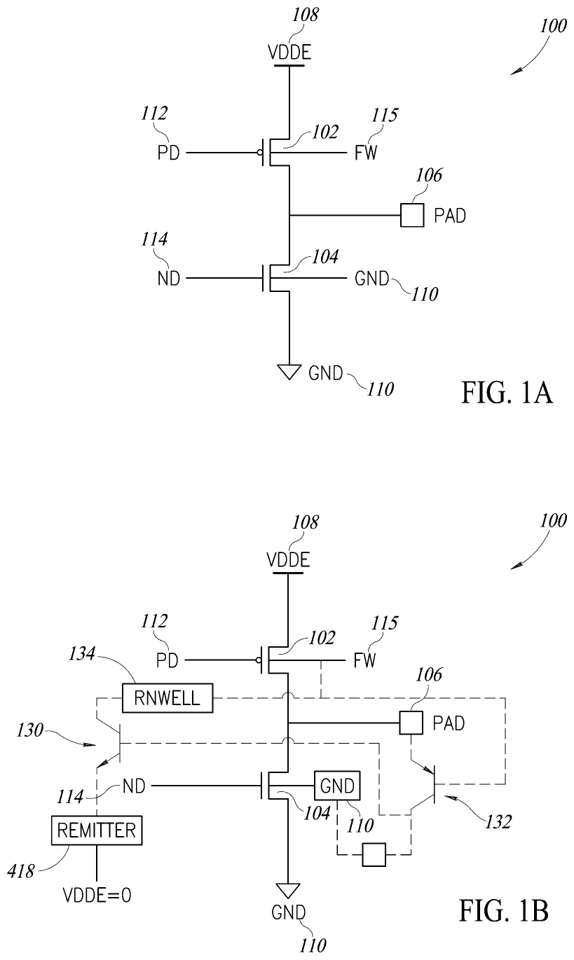

FIG. 1A is a conventional topology of a transmit circuit 100. The transmit circuit 100 includes two MOSFETs coupled to an output contact (PAD). Each of the two MOSFETs can drive the output contact with a control signal. The MOSFETs are coupled to an input/output (I/O) domain voltage supply (VDDE). An operation voltage of the VDDE can be compatible with an operation technology of the MOSFETs (e.g., 1.8V, 3.3V, 5V, etc). In fail-safe and fail-tolerant conditions the output contact can operate in two conditions. Either the IO buffer supply could be zero and the PAD is driven to buffer supply voltage or more by external chip or the IO buffer supply is still present but the PAD may be coupled to a high-voltage stage with a voltage higher than the operating voltage of the IO buffer.

The circuit 100 includes a first transistor 102 coupled to a voltage supply 108 and an output contact (PAD) 106, and a second transistor 104 coupled to the output contact (PAD) 106 and a reference node 110. In various embodiments, the reference node 110 is coupled to an electrical ground. In various embodiments, the first and second transistors 102, 104 are MOSFETs. The first transistor 102 is PMOS and the second transistor 104 is NMOS. A first control signal PD 112 is applied to a gate terminal of the PMOS 102. A second control signal ND 114 is applied to a gate terminal of the NMOS 104. The body terminal of the transistor 104 is coupled to the ground 110, while the body terminal of the transistor 102 is coupled to a voltage FW 115. The voltage FW 115 can be a maximum voltage between the voltage supply 108 and the PAD 106.

In some embodiments, the voltage supply 108 is an I/O domain voltage supply (VDDE). A voltage of the voltage supply 108 may be corresponding to the operation technology of the PMOS 102 and the NMOS 104.

FIG. 1B is a circuit 100 in use as a fail-safe and fail-tolerant input/output (IO) interface. This circuit includes floating n-wells that will be described in more detail below, that create latchup configurations in use. To increase the latchup robustness of such IOs, conventional designs increase the physical spacing or distance between the floating n-wells and other n-well(s) in a semiconductor substrate in which these components are formed. This spacing helps in reducing a gain of parasitic bipolar junction transistors formed in an equivalent silicon control rectifier (SCR) circuit. This spacing value or distance is dependent on a maximum voltage difference between floating n-well and adjacent n-well(s). This distance can range from 6 to 30 micrometers (um) in one example. Increasing the spacing to avoid latchup increases a base region of lateral parasitic NPN and decreases the gain. The base region size depends on a voltage difference between an anode and cathode (Vac) of the parasitic SCR. The greater the voltage difference Vac results in more spacing of the base region. This spacing often includes several ground rings (such as greater than 3 or 4) that are formed between an n-well and an adjacent deep n-well.

This means more spacing between geometries that constitute the SCR. For fail-safe or fail tolerant IO's, the IO PAD 106 can be driven to a high voltage by an external chip, so the body terminal of PMOS also follows PAD while all the other nwells are either at zero voltage or low voltage than PAD. These IO's are more prone to latchup and by increasing the base width of parasitic bipolars layout can be made more robust against latchup.

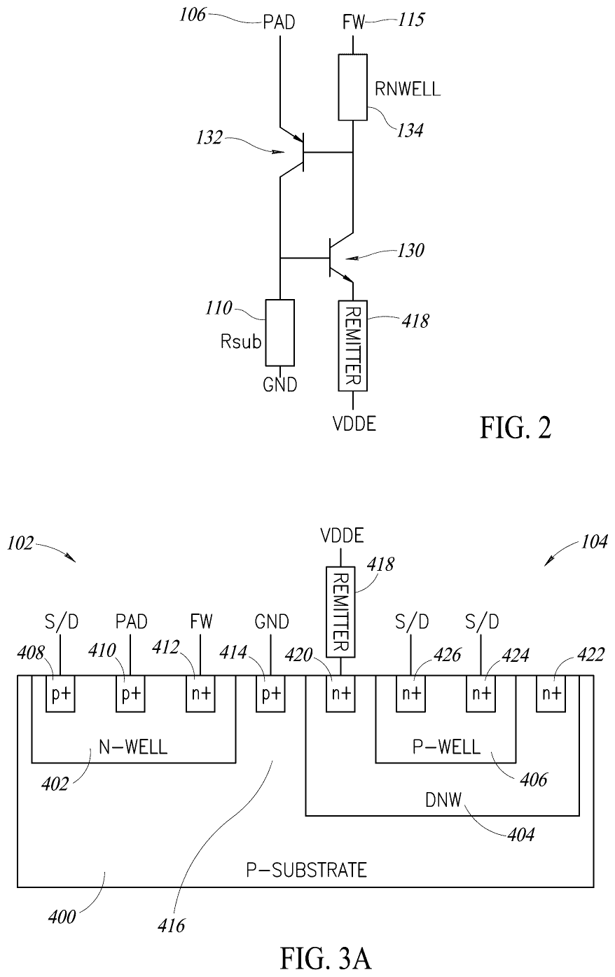

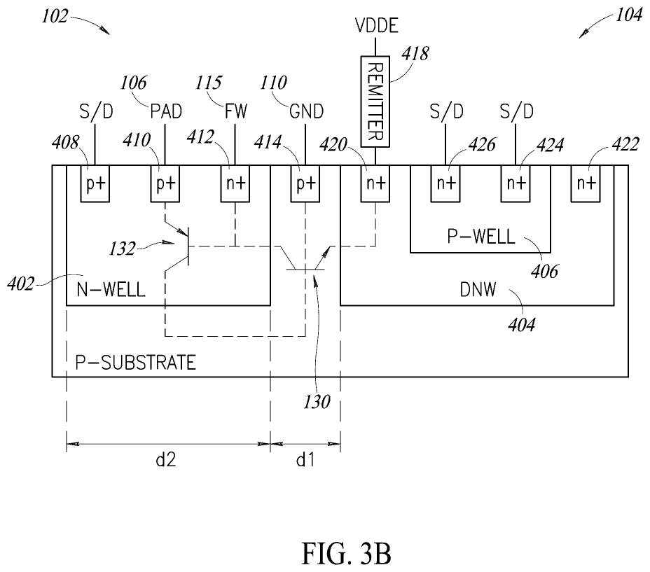

FIG. 1B includes the first PMOS transistor 102 that is coupled to VDDE 108 and the gate is coupled to the first control signal PD 112. The first PMOS transistor 102 is coupled between the PAD 106 and VDDE 108. The second NMOS transistor 104 is coupled between the PAD 106 and ground 110. In use, a first parasitic bipolar junction transistor (BJT) 130 and a second BJT 132 are formed in the substrate 400. FIGS. 1B, 2, and 3A-3B are described collectively for case of understanding. As can be seeing in FIG. 3A, a substrate 400 is a p-type substate. A first n-well 402 is adjacent to a second deep n-well (DNW) 404. A p-well 406 is formed in the DNW 404. The first PMOS transistor 102 is formed in the first n-well 402. The second NMOS transistor 104 is formed in the DNW 404. The embodiments in FIGS. 3A-3B are directed to a metal oxide semiconductor (MOS) configuration. Later embodiments are described that are directed to a diode configuration.

Two avoid the leakage current in fail-safe and fail-tolerant IO's the first n-well 402 of the PMOS transistor 102 is not connected to supply. It is dynamically switched between supply and PAD 106 through MOS switches. The higher voltage between PAD and supply is connected to the first n-well 402 (called floating well or FW) through the MOS switches. Similarly, either the ESD P-diode (connected between PAD and supply) is removed, and some other ESD protection device are used with respect to ground or the first n-well is connected to another ESD rail (called as floating rail) that follows PAD 106 in case a supply is lower than PAD.

In fail-safe or fail tolerant conditions, there will be some first n-wells in layout whose potential is controlled by the PAD 106, while there are another n-wells, which constitute the devices that are not part of IO driver or ESD strategy (e.g., level shifter whose bulk is connected to supply), are at zero voltage or at voltage less that of the PAD. This gives rise to potential latchup configurations within the IO interface.

The first PMOS transistor 102 includes a plurality of heavily doped P regions 408, 410. Nwell is biased using heavily doped N regions 412 all these are included in the first n-well 402. Source/drain regions of the first PMOS transistor 102 are coupled to a first one 408 of the plurality of heavily doped P regions. The PAD 106 is coupled to a second one 410 of the plurality of heavily doped P regions. The voltage FW 115 is coupled to a third one 412 of the plurality of heavily doped N regions in the n-well 402.

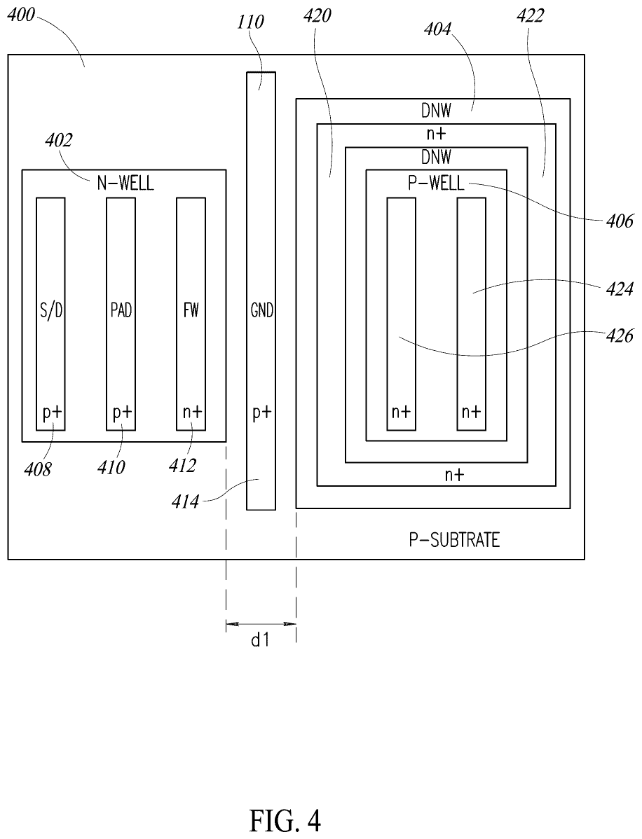

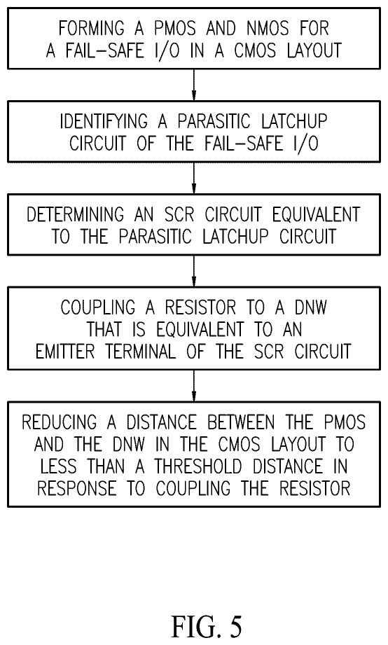

Ground 110 is coupled to a heavily doped P region 414 that is formed in the substrate 400 in an area 416 between the first n-well 402 and the DNW 404. The area 416 is significantly reduced in the present disclosure by inclusion of a resistor 418, REMITTER. The resistor 418 is coupled to a first one 420 of a plurality of heavily doped N regions formed in the DNW 404. A second one 422 of the plurality of heavily doped N regions is spaced from the first one of the plurality of heavily doped N regions by the p-well 406 in the cross-sectional view. As can be seen in FIG. 4, the first and the second ones 420 and 422 are part of a ring or n-well that surrounds the p-well 406.

A third one 424 and a fourth one 426 of the plurality of heavily doped N regions are formed in the p-well 406 in the DNW 404. As can be seen in FIG. 4, these are two parallel or substantially parallel doping regions in the p-well. The third and fourth ones 424, 426 are coupled to source/drain regions of the second NMOS transistor 104.

As can be seen in FIG. 3B, the terminals of the PMOS and NMOS transistors are formed in heavily doped N-type and P-type regions, which in operation, form emitter, collector, and base terminals of parasitic N-P-N and P-N-P BJTs, BJT130 and BJT 132, respectively. The inclusion of REMITTER 418 allows for this significant reduction in the overall area used by this circuit. In particular, the distance d1, in FIG. 3B can be made smaller than a dimension d2. In one embodiment, only a single ground line, P+ region 414 may be formed or needed between the n-well 402 and the DNW 404. This is a significant size reduction as compared to previous designs where multiple ground lines were needed to create sufficient space to manage latch up between the DNW and the n-well 402.

FIG. 4 is a top down view of the silicon substrate 400 with the various doped regions. The substrate 400 includes P-type dopants. The first n-well 402 is formed within the substrate. The first and second heavily doped regions 408, 410 are in the first n-well 402. The first and second heavily doped regions 408,410 have a longest dimension in a first direction. The first and second heavily doped regions 408,410 are substantially parallel to each other. A first heavily doped N+ region 412 is also formed in the first n-well 402. The first heavily doped N+ region 412 has a longest dimension in the first direction and is substantially parallel to the first and second heavily doped P+ regions 408, 410.

Another heavily doped P+ region 414 is formed in the substrate adjacent to the n-well 402. This heavily doped P+ region 414 is formed in the area 416 between the n-well 402 and the DNW 404.

The disclosure is to eliminate or substantially reduce the latchup problems while not wasting area used to space out the base region of NPN. The disclosure works only the case where the DNW is used only to isolate the p-substrate of NMOS device, resistors, capacitors and ESD N diodes. It should not have any P+/NWELL junction inside this. The disclosure is to connect the DNW, which is isolating the p-substrate, to VDDE through a resistor having value in kohm called Remitter. Said differently, the solution can be used for any device which is present inside a DNW. The limiting condition is that inside that DNW, there should not be p+/nwell junction. The DNW is the emitter side of parasitic npn. Hence The resistor connected to this DNW acts as Remiiter which decreases the current gain of the npn.

There is a significant area savings by including this resistor, Remitter. It is envisioned that Remitter will be formed outside the ground ring 110. The ground ring 110 in FIG. 4 may be formed to be completely around the DNW 404. The ground ring 110 could also extend completely around the n-well 402. In an alternative embodiment, the Remitter can be formed within the DNW.

The resistor, Remitter can be designed using a minimum dimension of poly resistor. The remitter should not be diffusion or a well resistor. With the inclusion of Remitter, a dimension d1 between the DNW 404 and the n-well 402, can be in the range of 3.3 and 7 microns, inclusive. These dimensions are one example and many dimensions are achievable.

The present disclosure is directed to a device that includes a set of complementary metal-oxide semiconductor (CMOS) transistors including a P-type substrate, a first N-type region in the substrate, a second N-type region in the substrate spaced from the first N-type region, the second N-type region being a deep-NWELL (DNW). A first heavily doped P-type region between the first and second N-type regions, the first heavily doped P-type region being coupled to ground. A second heavily doped P-type region in the first N-type region, the second heavily doped P-type region being coupled to an output terminal. A first heavily doped N-type region in the first N-type region, the first heavily doped N-type region being coupled to a floating-Well (FW) terminal. A second heavily doped N-type region in the second N-type region and a resistor coupled to the DNW, the resistor being coupled to a voltage supply terminal.

The resistor is coupled to an emitter terminal of a first parasitic bipolar junction transistor (BJT). The first BJT is an N-P-N BJT, the DNW being the emitter terminal of the first parasitic BJT and the first heavily doped N-type region being the collector terminal of the first parasitic BJT. A second parasitic BJT is coupled to the first parasitic BJT, the second parasitic BJT being a P-N-P BJT, and a base terminal of the second parasitic BJT being coupled to the collector terminal of the first parasitic BJT. An emitter terminal of the second parasitic BJT is coupled to the second heavily doped P-type region.

A combination of the first and second parasitic BJTs are equivalent to a silicon control rectifier (SCR), and the SCR is a latchup circuit of the set of CMOS transistors. The set of CMOS transistors are an input/output (I/O) interface operating in a fail-safe or fail-tolerant mode. The resistor is an on-chip resistor coupled to the DNW. The resistor reduces a gain of the first parasitic BJT and limits an electrical current flowing from the collector terminal to the emitter terminal of the first parasitic BJT.

A method includes forming a fail-safe input/output (I/O) on a complementary metal-oxide semiconductor (CMOS) layout by coupling an I/O interface to an output terminal. Forming the fail-safe I/O includes coupling a PMOS to the output terminal, the PMOS being formed in a P-type substrate of the CMOS layout, the PMOS including a first heavily doped N-type region and a first heavily doped P-type region in a first N-type region, the first heavily doped N-type region coupling to a floating-Well (FW) terminal and the first heavily doped P-type region coupling to the output terminal. Coupling an NMOS to the output terminal, the NMOS being formed in the P-type substrate, the NMOS including a second heavily doped N-type region in a second N-type region and a second heavily doped P-type region in the P-type substrate, the second heavily doped P-type region coupling to ground, and the second N-type region being laterally spaced from the first N-type region with a distance. Coupling a resistor to the second heavily doped N-type region, the resistor coupling a voltage supply to the second N-type region, and the coupling the resistor reducing an electrical current leakage to a parasitic latchup circuit.

The method includes the second N-type region being a deep-NWELL (DNW). The parasitic latchup circuit having parasitic bipolar junction transistors (BJTs) and the resistor being coupled to an emitter terminal of one of the parasitic BJTs. The distance has a threshold, the threshold being determined to limit the current leakage of the parasitic latchup circuit. The resistor causing the distance being less than the threshold.

A method that includes forming a complementary metal-oxide semiconductor (CMOS) layout having a threshold of area, the threshold being determined based on the voltage difference between PAD and supply (anode-cathode voltage of SCR, Vac), forming the CMOS layout including: forming a deep N-Well (DNW) region in a P-type substrate; forming an N-Well region in the substrate, the N-Well region is laterally spaced from the DNW region by a distance; forming a first heavily doped P-type region in the N-Well region, the first heavily doped P-type region is coupled to an output terminal; forming a second heavily doped P-type region between the N-Well and the DNW regions, the second heavily doped P-type region is coupled to ground; forming a heavily doped N-type region in the N-Well region, the heavily doped N-type region is coupled to a floating-Well (FW) terminal, and the DNW, the first heavily doped P-type, the second heavily doped P-type, and the heavily doped N-type regions forming the parasitic latchup circuit; and forming a resistor on the DNW region, the resistor is coupled between the DNW region and a voltage supply, the resistor limiting the electrical current leakage of the parasitic latchup circuit, and in response, the area of the CMOS layout reduces to a value less than the threshold.

The distance being determined along a first direction between a right edge of the DNW and a left edge of the N-Well region, and the distance being less than a dimension of the N-Well in the first direction. The distance being less than a threshold, the threshold being between around 30 μm (which can be in the range of 18 and 30 μm), and the distance being between 3 to 7 μm. The threshold being between 700 to 800 μm2, and the value of the area being between 100 to 200 μm2.

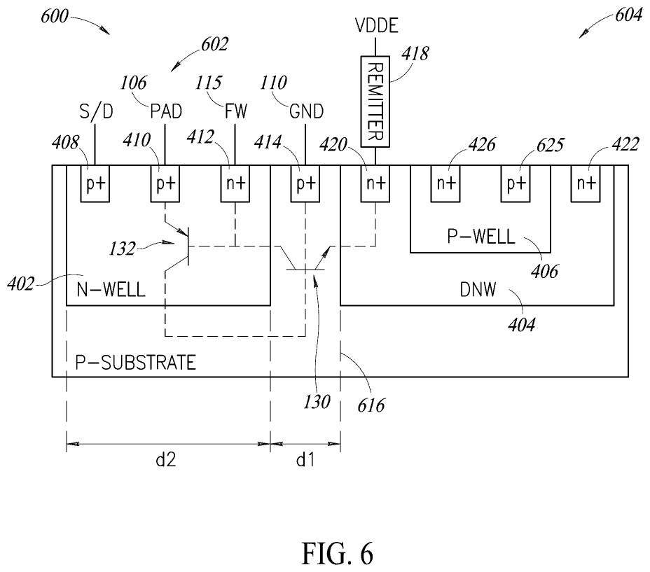

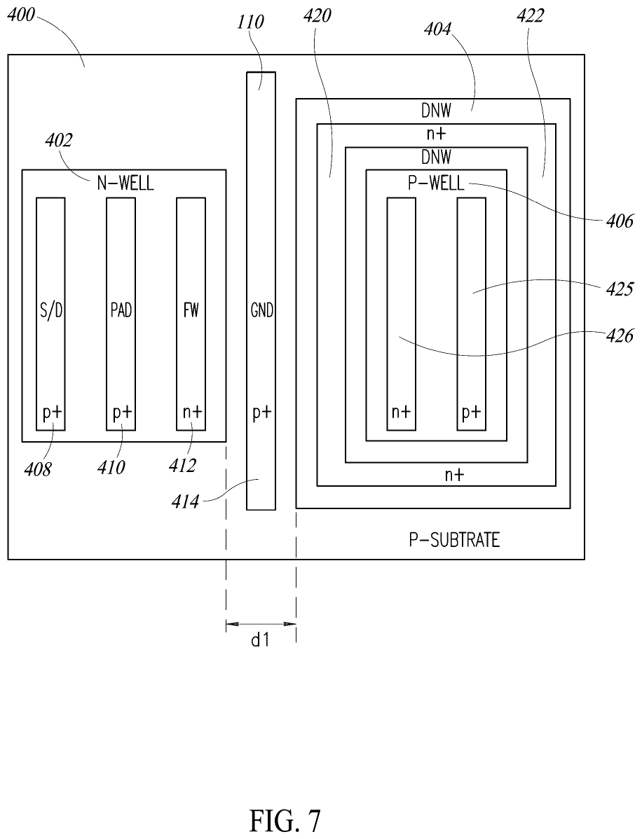

FIGS. 6 and 7 are cross-sectional and top down views of a diode configuration of the present disclosure. The diode configuration 600 can be formed with similar features to the MOS configuration. The features that are the same will be described with the same reference numbers. In the diode configuration, the p-type substrate 400 includes the first n-well 402 adjacent to the second deep n-well (DNW) 404. The p-well 406 is formed in the DNW 404. The first PMOS transistor 602 is formed in the first n-well 402. A diode 604 is formed in the DNW 404.

The first PMOS transistor 602 includes a plurality of heavily doped P regions 408, 410. Nwell is biased using heavily doped N regions 412 all these are included in the first n-well 402. Source/drain regions of the first PMOS transistor 102 are coupled to a first one 408 of the plurality of heavily doped P regions. The PAD 106 is coupled to a second one 410 of the plurality of heavily doped P regions. The voltage FW 115 is coupled to a third one 412 of the plurality of heavily doped N regions in the n-well 402.

Ground 110 is coupled to a heavily doped P region 414 that is formed in the substrate 400 in an area 416 between the first n-well 402 and the DNW 404. An area 616 between the transistor and the diode is significantly reduced in the present disclosure by inclusion of a resistor 418, REMITTER. The resistor 418 is coupled to a first one 420 of a plurality of heavily doped N regions formed in the DNW 404. A second one 422 of the plurality of heavily doped N regions is spaced from the first one of the plurality of heavily doped N regions by the p-well 406 in the cross-sectional view. As can be seen in FIG. 7, the first and the second ones 420 and 422 are part of a ring or n-well that surrounds the p-well 406.

A third one 426 of the plurality of heavily doped N regions are formed in the p-well 406 in the DNW 404. The p-well 406 includes a p+, heavily doped P region 625 that is adjacent to the n+ region 426.

FIG. 7 is a top down view of the silicon substrate 400 with the various doped regions. The substrate 400 includes P-type dopants. The first n-well 402 is formed within the substrate. The first and second heavily doped regions 408, 410 are in the first n-well 402. The first and second heavily doped regions 408,410 have a longest dimension in a first direction. The first and second heavily doped regions 408,410 are substantially parallel to each other. A first heavily doped N+ region 412 is also formed in the first n-well 402. The first heavily doped N+ region 412 has a longest dimension in the first direction and is substantially parallel to the first and second heavily doped P+ regions 408, 410.

Another heavily doped P+ region 414 is formed in the substrate adjacent to the n-well 402. This heavily doped P+ region 414 is formed in the area 416 between the n-well 402 and the DNW 404. The p-well 406 in the DNW 404 includes both the n+ region 426 and the p+ region 635. As noted above, the disclosure is to eliminate or substantially reduce the latchup problems while not wasting area used to space out the base region of NPN with ESD N diodes. The disclosure is to connect the DNW, which is isolating the p-substrate, to VDDE through a resistor having value in kohm called Remitter.

As with the MOS configuration, there is a significant area savings by including this resistor, Remitter, in the diode configuration. It is envisioned that Remitter will be formed outside the ground ring 110. The ground ring 110 in FIG. 7 may be formed to be completely around the DNW 404. The ground ring 110 could also extend completely around the n-well 402. In an alternative embodiment, the Remitter can be formed within the DNW.

The resistor, Remitter can be designed using a minimum dimension of poly resistor. The remitter should not be diffusion or a well resistor. With the inclusion of Remitter, a dimension d1 between the DNW 404 and the n-well 402, can be in the range of 3.3 and 7 microns, inclusive. These dimensions are one example and many dimensions are achievable for the diode configuration.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device comprising:
a P-type substrate;
a first N-type region in the substrate;
a second N-type region in the substrate spaced from the first N-type region by less than 7 microns, the second N-type region being a deep-NWELL (DNW);
a first heavily doped P-type region between the first N-type region and the DNW, the first heavily doped P-type region being coupled to ground;
a second heavily doped P-type region in the first N-type region;
a first heavily doped N-type region in the first N-type region;
a second heavily doped N-type region in the DNW; and
a resistor coupled to the second heavily doped N-type region.

2. The device of claim 1 wherein the resistor is coupled to an emitter terminal of a first parasitic bipolar junction transistor (BJT), the first heavily doped P-type region being coupled to ground, the second heavily doped P-type region being coupled to an output terminal, the first heavily doped N-type region being coupled to a floating-Well (FW) terminal, the resistor being coupled to a voltage supply terminal.

3. The device of claim 2 wherein the first BJT is an N-P-N BJT, the DNW being the emitter terminal of the first parasitic BJT and the first heavily doped N-type region being the collector terminal of the first parasitic BJT.

4. The device of claim 3 wherein a second parasitic BJT is coupled to the first parasitic BJT, the second parasitic BJT being a P-N-P BJT, and a base terminal of the second parasitic BJT being coupled to the collector terminal of the first parasitic BJT.

5. The device of claim 4 wherein an emitter terminal of the second parasitic BJT is coupled to the second heavily doped P-type region.

6. The device of claim 5 wherein a combination of the first and second parasitic BJTs are equivalent to a silicon control rectifier (SCR), and the SCR is a latchup circuit of a set of CMOS transistors.

7. The device of claim 6 wherein the set of CMOS transistors are an input/output (I/O) interface operating in a fail-safe or fail-tolerant mode.

8. The device of claim 7 wherein the resistor is an on-chip resistor coupled to the DNW.

9. The device of claim 8 wherein the resistor reduces a gain of the first parasitic BJT and limits an electrical current flowing from the collector terminal to the emitter terminal of the first parasitic BJT.

10. The device of claim 1 comprising:
a p-well in the DNW;
a third heavily doped N-type region in the p-well; and
a fourth heavily doped N-type region in the p-well.

11. The device of claim 1 comprising:
a p-well in the DNW;
a third heavily doped N-type region in the p-well; and
a third heavily doped P-type region in the p-well.

12. A method, comprising:
forming a fail-safe input/output (I/O) on a complementary metal-oxide semiconductor (CMOS) layout by coupling an I/O interface to an output terminal, forming the fail-safe I/O includes:
coupling a PMOS to the output terminal, the PMOS being in a P-type substrate of the CMOS layout, the PMOS including a first heavily doped N-type region and a first heavily doped P-type region in a first N-type region;
coupling the first heavily doped N-type region to a floating-Well (FW) terminal;
coupling the first heavily doped P-type region to the output terminal;
coupling an NMOS to the output terminal, the NMOS being in the P-type substrate, the NMOS including a second heavily doped N-type region in a second N-type region and a second heavily doped P-type region in the P-type substrate;
coupling the second heavily doped P-type region to ground and the second N-type region being laterally spaced from the first N-type region with a distance less than 7 micrometers; and
coupling a resistor to the second heavily doped N-type region, the resistor coupling a voltage supply to the second N-type region.

13. The method of claim 12 wherein the second N-type region being a deep-NWELL (DNW).

14. The method of claim 12 wherein the parasitic latchup circuit having parasitic bipolar junction transistors (BJTs) and the resistor being coupled to an emitter terminal of one of the parasitic BJTs.

15. The method of claim 12 wherein the distance has a threshold, the threshold being determined to limit the current leakage of the parasitic latchup circuit.

16. A method comprising:
forming a complementary metal-oxide semiconductor (CMOS) layout having a threshold of area, the threshold being determined based on an electrical current leakage of a parasitic latchup circuit, forming the CMOS layout including:
forming a deep N-Well (DNW) region in a P-type substrate;
forming an N-Well region in the substrate, the N-Well region is laterally spaced from the DNW region by a distance;
forming a first heavily doped P-type region in the N-Well region, the first heavily doped P-type region is coupled to an output terminal;
forming a second heavily doped P-type region between the N-Well and the DNW regions, the second heavily doped P-type region is coupled to ground;
forming a heavily doped N-type region in the N-Well region, the heavily doped N-type region is coupled to a floating-Well (FW) terminal, and the DNW, the first heavily doped P-type, the second heavily doped P-type, and the heavily doped N-type regions forming the parasitic latchup circuit; and
forming a resistor on the DNW region, the resistor is coupled between the DNW region and a voltage supply, the resistor limiting the electrical current leakage of the parasitic latchup circuit, and in response, the area of the CMOS layout reduces to a value less than the threshold.

17. The method of claim 16 wherein the distance being determined along a first direction between a right edge of the DNW and a left edge of the N-Well region, and the distance being less than a dimension of the N-Well in the first direction.

18. The method of claim 15 wherein the distance being less than a threshold, the threshold being around 30 μm, and the distance being between 3 to 7 μm.

19. The method of claim 16 wherein the threshold being between 700 to 800 μm², and the value of the area being between 100 to 200 μm².
